(19) United States
(12) Patent Application Publication
(10) Pub. No.: US 2010/0027344 A1
(43) Pub. Date: Feb. 4, 2010

(54) SEMICONDUCTOR MEMORY DEVICE

(76) Inventors: Reiji MOCHIDA, Osaka (JP); Yasuhiro TOMITA, Osaka (JP); Kazuyuki KOUNO, Osaka (JP); Hoshihide HARUYAMA, Kyoto (JP); Masayoshi NAKAYAMA, Shiga (JP)

Correspondence Address: MCDERMOTT WILL & EMERY LLP, 600 13TH STREET, NW, WASHINGTON, DC, 20005-3096, US

(21) Appl. No.: 12/510,745

(22) Filed: Jul. 28, 2009

(30) Foreign Application Priority Data
Jul. 31, 2008 (JP) 2008-197901
Jun. 2, 2009 (JP) 2009-133276

(51) Int. Cl. G11C 16/04; G11C 7/00; G11C 5/14

(52) U.S. Cl. 365/185.18; 365/194; 365/189.11; 365/189.09

(57) ABSTRACT

A drain voltage generator circuit includes a first switching element coupled between a first power supply voltage and an output end of the drain voltage generator circuit, a second switching element coupled in parallel to the first switching element and having a smaller current capability than that of the first switching element, and a control circuit for turning ON the second switching element and then the first switching element, and generates a voltage to supply to a drain of a memory cell. A source of the memory cell is set to be floated or grounded by a transistor.

### CROSS-REFERENCE TO RELATED APPLICATION

This application claims priority under 35 U.S.C. §119(a) on Japanese Patent Application No. 2008-197901 filed on Jul. 31, 2008, and Japanese Patent Application No. 2009-133276 filed on Jun. 2, 2009, and the entire contents of which are hereby incorporated by reference.

### BACKGROUND OF THE INVENTION

The present disclosure relates to semiconductor memory devices, and more particularly, relates to nonvolatile memories such as EEPROMs (electrically erasable programmable read only memories) and the like.

In an EEPROM, a memory content of a memory cell can be erased and rewritten using an electric signal. Specifically, a word line to which a gate of a memory cell is coupled is activated to select the memory cell, a predetermined voltage is applied to a drain of the memory cell according to a data write control signal, and a source of the memory cell is set to be grounded or floating according to a program control signal. When the source of the memory cell is grounded, hot electrons are injected into the memory cell, and thus, L data is written. On the other hand, when the source of the memory cell is floated, a tunnel current is generated, and thus, H data is written.

When a drain voltage of the memory cell is rapidly raised, a transitional current flows in another memory cell sharing the word line with the memory cell. Thus, hot electrons are injected into the non-selected memory cell to increase a threshold voltage and, accordingly, L data might be written by error therein. To deal with this problem, there are EEPROMs in which a drain voltage generator circuit for causing a drain voltage of a memory cell to slowly rise is provided (see, for example, Japanese Published Application No. 2000-11668).

### SUMMARY OF THE INVENTION

In a known drain voltage generator circuit, to ensure a sufficient rise time of a drain voltage of a memory cell, the current capability of a transistor for outputting the drain voltage has to be small. However, when the current capability is reduced, a voltage drop is caused, and thus, a sufficiently large drain voltage might not be able to be supplied to a drain of the memory cell. There is another problem. That is, because the known drain voltage generator circuit has a mechanism in which a voltage supplied to a gate of the transistor is made to flow to a ground node except when data is being written, the power consumption of the known drain voltage generator circuit is large.

In view of the above-described problems, according to the present disclosure, an example read only semiconductor memory device described below in which a memory content of a memory cell can be erased and rewritten using an electric signal may advantageously ensure a sufficient rise time of a drain voltage of the memory cell and supply a sufficiently large drain voltage to the memory cell with small power consumption.

To solve the above-described problems, the following means has been devised. That is, an example read only semiconductor memory device in which a memory content of a memory cell can be erased and rewritten using an electric signal includes a drain voltage generator circuit for generating, according to a data write control signal, a voltage to be supplied to a drain of the memory cell. The drain voltage generator circuit includes a first switching element coupled between a first power supply voltage and an output end of the drain voltage generator circuit, a second switching element coupled in parallel to the first switching element and having a smaller current capability than that of the first switching element, and a control circuit for turning ON the second switching element and then the first switching element according to the data write control signal.

Thus, an output voltage of the drain voltage generator circuit is slowly increased while only the second switching element having a small current capability is ON, and thereafter, the first switching element is turned ON, so that the output voltage is increased to reach a sufficient high level. Therefore, a sufficient rise time of the drain voltage of the memory cell can be ensured and a sufficiently large drain voltage can be supplied to the memory cell. Moreover, the first and second switching elements are OFF except for when data is being written, and thus, a current does not flow in the ground and power consumption is reduced.

The drain voltage generator circuit preferably includes a delay circuit for delaying a control signal output from the control circuit to transmit the delayed signal to the second switching element. Thus, a rise time of an output voltage of the drain voltage generator circuit can be adjusted.

### BRIEF DESCRIPTION OF THE DRAWINGS

FIG. 1 is a block diagram illustrating a configuration of a semiconductor memory device according to an embodiment of the present invention.

FIG. 2 is a waveform diagram of an operation of a drain voltage generator circuit of FIG. 1.

FIG. 3 is a block diagram illustrating a configuration of a modified example of the drain voltage generator circuit.

FIG. 4 is a waveform diagram of an operation of a drain voltage generator circuit of FIG. 3.

FIG. 5 is a block diagram illustrating a configuration of another modified example of the drain voltage generator circuit.

FIG. 6 is a block diagram illustrating a configuration of still another modified example of the drain voltage generator circuit.

FIG. 7 is a block diagram illustrating an example configuration of a control circuit.

FIG. 8 is a block diagram illustrating another example configuration of the control circuit.

FIG. 9 is a block diagram illustrating an example configuration of a delay circuit in the control circuit.

FIG. 10 is a block diagram illustrating another example configuration of the delay circuit in the control circuit.

### DETAILED DESCRIPTION OF THE INVENTION

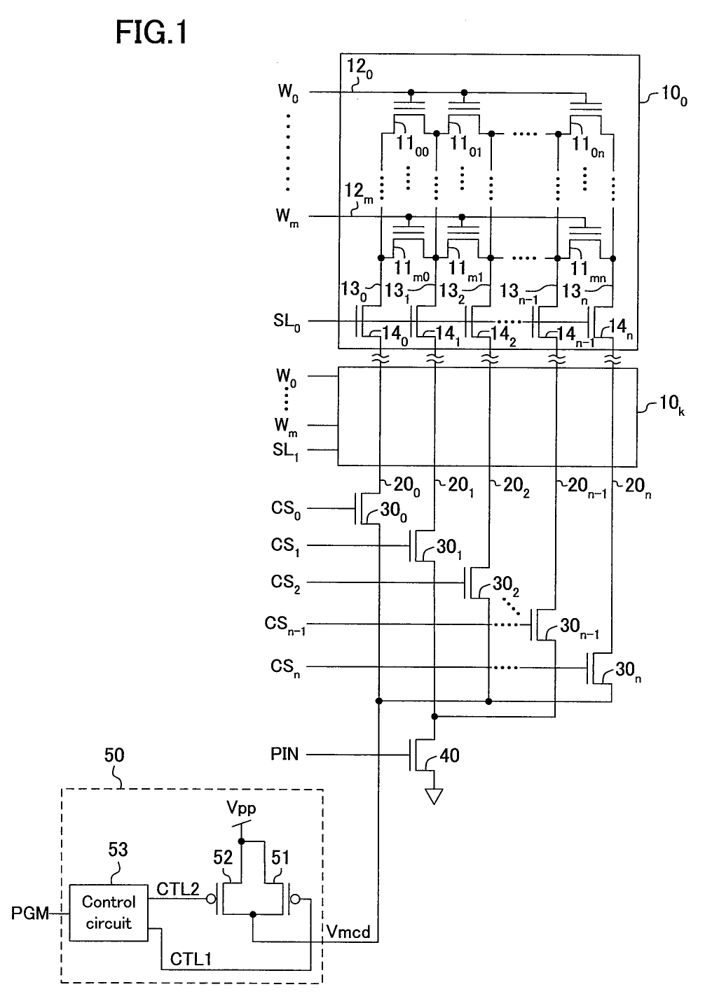

FIG. 1 is a block diagram illustrating a configuration of a semiconductor memory device according to an embodiment. The semiconductor memory device of the embodiment is a sub-array type semiconductor memory device including k+1 sub-arrays 10₀ through 10ₖ. Each of the sub-arrays 10₀ through 10ₖ includes (m+1)×(n+1) memory cells 11₀₀ through 11ₘₙ arranged in a matrix. Moreover, m+1 word lines 12₀ through 12ₘ respectively corresponding to rows of the memory cells 11₀₀ through 11ₘₙ are provided. Specifically, to each of the word lines 12, gates of n+1 memory cells 11 belonging to an associated one of the rows are coupled. Furthermore, n+1 bit lines 13₀ through 13ₙ are provided so as to respectively correspond to columns of the memory cells 11₀₀ through 11ₘₙ. Specifically, to each of even numbered bit lines 13, drains of (m+1)×2 memory cells 11 belonging to associated ones of the columns which are located adjacent to each other are coupled and, to each of odd numbered bit lines 13, sources of the (m+1)×2 memory cells 11 belonging to associated ones of the columns which are located adjacent to each other are coupled.

Furthermore, each of the sub-arrays 10₀ through 10ₖ includes n+1 select transistors 14₀ through 14ₙ each of which is switching controlled by a common select signal SL. Drains of the select transistors 14₀ through 14ₙ are respectively coupled to ends of the bit lines 13₀ through 13ₙ. Sources of the select transistors 14₀ through 14ₙ in each of the sub-arrays 10₀ through 10ₖ are respectively coupled to n+1 main bit lines 20₀ through 20ₙ.

Drains of n+1 column select transistors 30₀ through 30ₙ are respectively coupled to ends of the main bit lines 20. The column select transistors 30₀ through 30ₙ are switching controlled by column select signals CS₀ through CSₙ input to gates thereof so that a predetermine one of the main bit lines 20 is selected when data is written.

Sources of odd numbered column select transistors 30 are coupled to a drain of a transistor 40. A source of the transistor 40 is grounded. The transistor 40 sets, according to a program control signal PIN input to a gate thereof, a source of the memory cell 11 coupled to the selected one of the main bit lines 20 by the column select signals CS to be floated or grounded. Specifically, the transistor 40 is controlled so as to be activated when L data is written, and is deactivated when H data is written.

On the other hand, sources of even numbered column select transistors 30 are coupled to an output of a drain voltage generator circuit 50. When data is written, the drain voltage generator circuit 50 supplies, according to a data write control signal PGM, a voltage Vmcd to a drain of the memory cell 11 coupled to the selected one of the main bit lines 20 by the column select signals CS.

The drain voltage generator circuit 50 includes a transistor 51 having a drain coupled to a data write voltage Vpp, a source coupled to an output end of the voltage Vmcd and a gate to which a control signal CTL1 is input, a transistor 52 having a drain coupled to the data write voltage Vpp, a source coupled to an output end of the voltage Vmcd and a gate to which a control signal CTL2 is input, and a control circuit 53 for outputting the control signals CTL1 and CTL2 according to the data write control signal PGM. In this case, the transistors 51 and 52 are configured so that the current capability of the transistor 52 is smaller than the current capability of the transistor 51. The control circuit 53 outputs the control signals CTL1 and CTL2 so that the transistor 52 is turned ON and then the transistor 51 is turned ON.

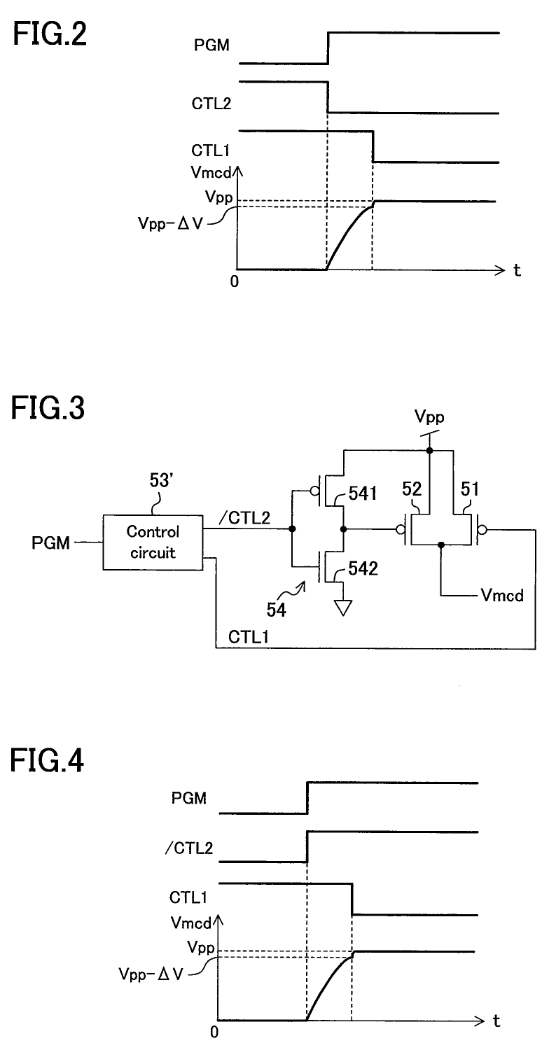

FIG. 2 is a waveform diagram of an operation of the drain voltage generator circuit 50. When the data write control signal PGM is driven to H level, the control signal CTL2 goes L level. Accordingly, the transistor 52 is turned ON first. However, since the current capability of the transistor 52 is small, the transistor 52 cannot output the data write voltage Vpp at once, and thus the voltage Vmcd slowly rises. Moreover, due to a voltage drop ΔV in the transistor 52, the voltage Vmcd does not reach the data write voltage Vpp. After a lapse of a predetermined time since the data write control signal PGM is driven to H level, the control signal CTL1 goes L level. Thus, the transistor 51 having a large current capability is turned ON. As a result, the voltage Vmcd is increased to a level close to the data write voltage Vpp.

The data write operation of the semiconductor memory device configured in the above-described manner will be described using, as an example, the case where data is written in the memory cell 11₀₀ in the sub-array 10₀. First, a select signal SL₀ is driven to H level to select the sub-array 10₀. Then, the word line control signal W₀ and the column select signals CS₀ and CS₁ are driven to H level to select the memory cell 11₀₀. Thereafter, the data write control signal PGM and the program control signal PIN are activated, and thereby, a source of the memory cell 11₀₀ is grounded and the voltage Vmcd is supplied to a drain thereof. Thus, hot electrons are injected into the memory cell 11₀₀, and accordingly, L data is written. In contrast, when only the data write control signal PGM is activated, the source of the memory cell 11₀₀ is floated, and the voltage Vmcd is supplied to the drain thereof. Thus, a tunnel current is generated in the memory cell 11₀₀, and accordingly, H data is written.

Based on the above, according to this embodiment, a sufficiently large voltage can be slowly applied to a drain of a memory cell when data is written. Thus, without causing writing of data in another memory cell by error, the data can be reliably written on a selected memory cell. Furthermore, the transistors 51 and 52 are turned OFF except when data is being written, and thus, a current does not flow to the ground. Therefore, power consumption can be reduced.

### MODIFIED EXAMPLE 1 OF DRAIN VOLTAGE GENERATOR CIRCUIT

FIG. 3 is a block diagram illustrating a configuration of a modified example of the drain voltage generator circuit 50. A control circuit 53′ outputs a control signal CTL1 and a control signal /CTL2 which is logic inversion of the control signal CTL2 according to a data write control signal PGM. An inverter circuit 54 formed of transistors 541 and 542 is inserted between the control circuit 53′ and a gate of the transistor 52. The inverter circuit 54 logically inverts the control signal /CTL2 to input the inverted signal to the gate of the transistor 52. That is, the inverter circuit 54 serves as a delay circuit for delaying the control signal /CTL2 to transmit the delayed signal to the gate of the transistor 52.

FIG. 4 is a waveform diagram of an operation of the drain voltage generator circuit 50 of this modified example. When the data write control signal PGM is driven to H level, the control signal /CTL2 goes H level. Thus, an output of the inverter circuit 54 goes L level, and the transistor 52 is turned ON first. However, since the current capability of the transistor 52 is small, the transistor 52 cannot output the data write voltage Vpp at once, and thus the voltage Vmcd slowly rises. Moreover, due to a voltage drop ΔV in the transistor 52, the voltage Vmcd does not reach the data write voltage Vpp. After a lapse of a predetermined time since the data write control signal PGM is driven to H level, the control signal CTL1 goes L level. Thus, the transistor 51 having a large current capability is turned ON. As a result, the voltage Vmcd is increased to a level close to the data write voltage Vpp.

According to this modified example, a rise time of the voltage Vmcd can be adjusted by appropriately adjusting the size of the transistor 542.

### MODIFIED EXAMPLE 2 OF DRAIN VOLTAGE GENERATOR CIRCUIT

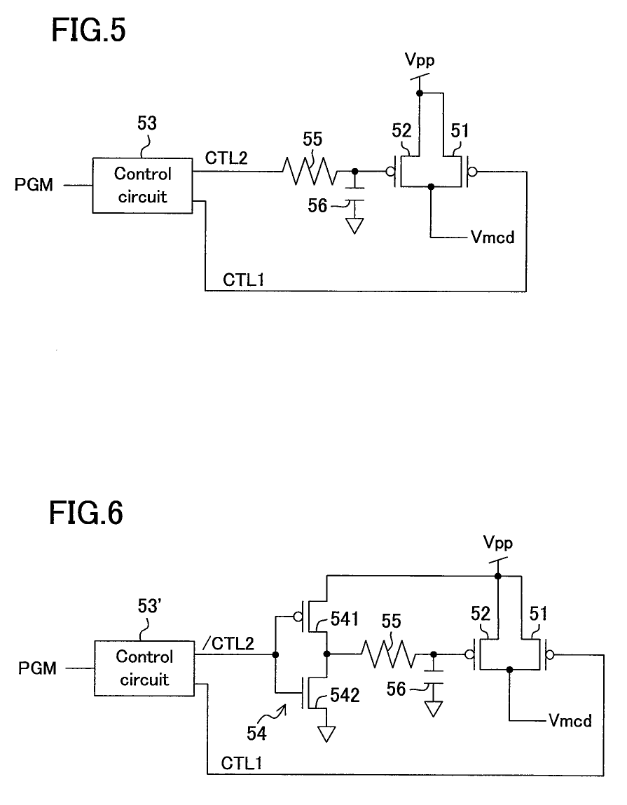

FIG. 5 is a block diagram illustrating a configuration of another modified example of the drain voltage generator circuit 50. A resistor element 55 and a capacitor element 56 are inserted between the control circuit 53 and the gate of the transistor 52. The resistor element 55 and the capacitor element 56 function as a delay circuit. Specifically, the control signal CTL2 is delayed through the resistor element 55 and the capacitor element 56 and is transmitted to the gate of the transistor 52. Note that the waveform of an operation of the drain voltage generator circuit 50 of this modified example is as shown in FIG. 2.

According to this modified example, the rise time of the voltage Vmcd can be adjusted by appropriately adjusting at least one of the sizes of the resistor element 55 and the capacitor element 56. Note that one of the resistor element 55 and the capacitor element 56 may be omitted.

### MODIFIED EXAMPLE 3 OF DRAIN VOLTAGE GENERATOR CIRCUIT

FIG. 6 is a block diagram illustrating a configuration of still another modified example of the drain voltage generator circuit 50. The drain voltage generator circuit of this modified example has a configuration in which the resistor element 55 and the capacitor element 56 are inserted between the inverter circuit 54 and the gate of the transistor 52 of the drain voltage generator circuit of FIG. 3.

According to this modified example, the rise time of the voltage Vmcd can be adjusted by appropriately adjusting at least one of the sizes of the transistor 542, the resistor element 55 and the capacitor element 56. Note that one of the resistor element 55 and the capacitor element 56 may be omitted.

The drain voltage generator circuit 50 of each of the above-described modified examples can damp the control signal CTL2 output from the control circuit 53, thereby causes the voltage Vmcd to rise more slowly and also adjusts the rise time of the voltage Vmcd.

### SPECIFIC EXAMPLES OF CONTROL CIRCUIT

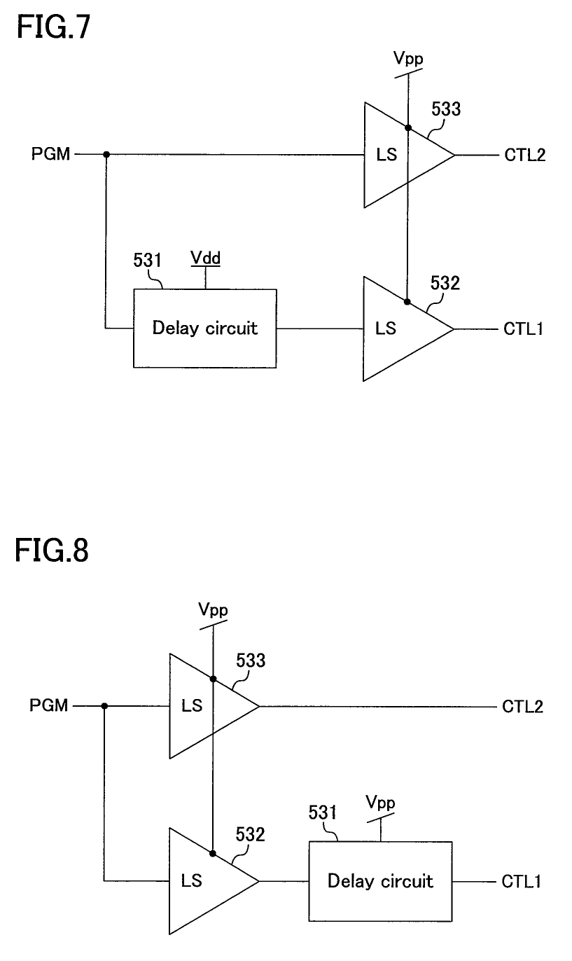

FIG. 7 is a block diagram illustrating an example configuration of the control circuit 53. The control circuit 53 has two paths for level shifting the data write control signal PGM to the data write voltage Vpp to output it. Through one of the paths, the data write control signal PGM is input directly to a level shifter 533 and the control signal CTL2 is output. The other one of the paths includes a delay circuit 531 having a lower power supply voltage Vdd than the data write voltage Vpp between the data write control signal PGM and the level shifter 532, and the control signal CLT2 is output and then the control signal CLT1 is output. Note that, as shown in FIG. 8, the delay circuit 531 may be arranged between the level shifter 532 and the control signal CLT1. In such a case, the power supply voltage of the delay circuit 531 is the data write voltage Vpp.

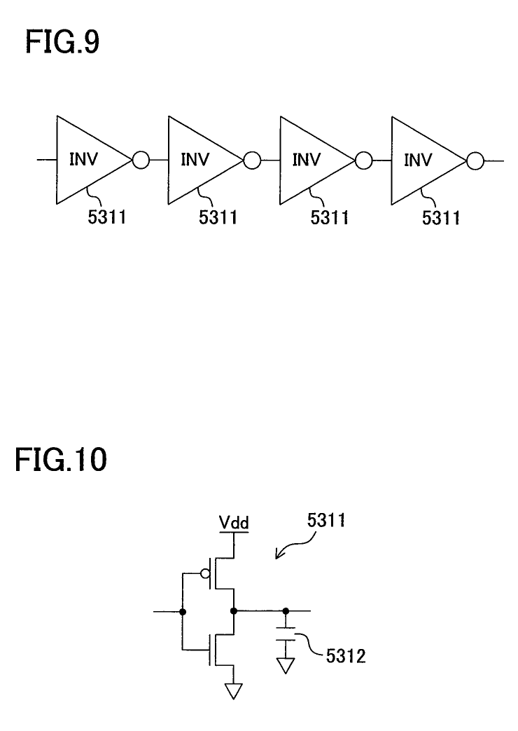

FIG. 9 is a block diagram illustrating an example configuration of the delay circuit 531. The delay circuit 531 can be formed of inverter circuits 5311 provided in a plurality of stages. FIG. 10 is a block diagram illustrating another example configuration of the delay circuit 531. The delay circuit 531 can be also formed of the inverter circuit 5311 and a capacitor element 5312 coupled to an output of the inverter circuit 5311.

What is claimed is:

1. A read only semiconductor memory device in which a memory content of a memory cell can be erased and rewritten using an electric signal, the device comprising: a drain voltage generator circuit for generating, according to a data write control signal, a voltage to be supplied to a drain of the memory cell,
wherein the drain voltage generator circuit includes a first switching element coupled between a first power supply voltage and an output end of the drain voltage generator circuit,
a second switching element coupled in parallel to the first switching element and having a smaller current capability than that of the first switching element, and
a control circuit for turning ON the second switching element and then the first switching element according to the data write control signal.

2. The semiconductor memory device of claim 1, wherein the drain voltage generator circuit includes a delay circuit for delaying a control signal output from the control circuit to transmit the delayed signal to the second switching element.

3. The semiconductor memory device of claim 2, wherein the delay circuit is an inverter circuit.

4. The semiconductor memory device of claim 2, wherein the delay circuit is a resistor element, a capacitor element, or a combination of a resistor element and a capacitor element.

5. The semiconductor memory device of claim 2, wherein the delay circuit includes:
an inverter circuit; and
a resistor element coupled to an output of the inverter circuit, a capacitor element coupled to the output, or a combination of a resistor element and a capacitor element coupled to the output.

6. The semiconductor memory device of claim 1, wherein the control circuit includes:
a second delay circuit for delaying the data write control signal input to the control circuit;
a first level shifter for level shifting an output of the second delay circuit to the first power supply voltage to output the level shifted output as a control signal for the first switching element; and
a second level shifter for level shifting the data write control signal input to the control circuit to the first power supply voltage to output the level shifted signal as a control signal for the second switching element.

7. The semiconductor memory device of claim 6, wherein the second delay circuit is formed of inverter circuits provided in a plurality of stages.

8. The semiconductor memory device of claim 6, wherein the second delay circuit includes an inverter circuit and a capacitor element coupled to an output of the inverter circuit.

9. The semiconductor memory device of claim 1, wherein the control circuit includes:
a first level shifter for level shifting the data write control signal input to the control circuit to the first power supply voltage;
a second level shifter for level shifting the data write control signal input to the control circuit to the first power supply voltage to output the level shifted signal as a control signal for the second switching element; and
a second delay circuit for delaying an output of the first level shifter to output the delayed output as a control signal for the first switching element.

10. The semiconductor memory device of claim 9, wherein the second delay circuit is formed of inverter circuits provided in a plurality of stages.

11. The semiconductor memory device of claim 9, wherein the second delay circuit includes an inverter circuit and a capacitor element coupled to an output of the inverter circuit.

12. The semiconductor memory device of claim 6, wherein the second delay circuit is operated with a second power supply voltage which is lower than the first power supply voltage.
